(19) United States
(12) Patent Application Publication
(10) Pub. No.: US 2025/0364972 A1
(43) Pub. Date: Nov. 27, 2025

(54) HIGH COUPLING COEFFICIENT RESONATOR MATCHING FOR PERFORMANCE

(71) Applicant: SKYWORKS SOLUTIONS, INC., Irvine, CA (US)

(72) Inventors: Yiliu Wang, Irvine, CA (US); Tomoya Komatsu, Irvine, CA (US); Nan Wu, Irvine, CA (US)

(21) Appl. No.: 19/214,709

(22) Filed: May 21, 2025

Related U.S. Application Data
(60) Provisional application No. 63/650,754, filed on May 22, 2024.

(51) Int. Cl. H03H 9/64; H03H 9/02; H03H 9/72

(52) U.S. Cl. CPC H03H 9/6483; H03H 9/725; H03H 9/02834

(57) ABSTRACT

Aspects and embodiments disclosed herein include an acoustic wave filter comprising an input and output port, a plurality of acoustic wave resonators electrically connected between the input and output port, and an impedance matching acoustic wave resonator. The impedance matching acoustic wave resonator is electrically connected on one side to a node between the plurality of acoustic wave resonators and one of the input or output port, and on a second side to one of ground or to the one of the input or output port. The impedance matching acoustic wave resonator has a resonance frequency below a low edge of a passband of the acoustic wave filter and an antiresonance frequency above a high edge of the passband of the acoustic wave filter. The impedance matching acoustic wave resonator may be a surface acoustic wave resonator having a multilayer piezoelectric substrate or a bulk acoustic wave resonator.

### CROSS-REFERENCE TO RELATED APPLICATIONS

This application claim priority under 35 U.S.C. § 119 (e) to U.S. Provisional Patent Application Ser. No. 63/650,754, titled “HIGH COUPLING COEFFICIENT RESONATOR MATCHING FOR PERFORMANCE,” filed May 22, 2024, the entire content of which is incorporated herein by reference for all purposes.

### BACKGROUND

### Field

Aspects and embodiments disclosed herein relate generally to radio frequency acoustic wave filters and to circuits and devices including same.

### Description of Related Technology

An acoustic wave filter can include a plurality of acoustic wave resonators arranged to filter a radio frequency signal. Examples of acoustic wave resonators include surface acoustic wave (SAW) resonators and bulk acoustic wave (BAW) resonators.

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, three acoustic wave filters can be arranged as a triplexer. As another example, four acoustic wave filters can be arranged as a quadplexer.

### SUMMARY

In accordance with one aspect, there is provided an acoustic wave filter. The acoustic wave filter comprises an input port, an output port, a plurality of acoustic wave resonators electrically connected between the input port and the output port, and an impedance matching acoustic wave resonator electrically connected on one side to a node between the plurality of acoustic wave resonators and one of the input port or the output port, and on a second side to one of ground or to the one of the input port or the output port, the impedance matching acoustic wave resonator having a resonance frequency below a low edge of a passband of the acoustic wave filter and an antiresonance frequency above a high edge of the passband of the acoustic wave filter, the impedance matching acoustic wave resonator being one of a surface acoustic wave resonator having a multilayer piezoelectric substrate or a bulk acoustic wave resonator.

In some embodiments, the impedance matching acoustic wave resonator is inductive at all frequencies within the passband of the acoustic wave filter.

In some embodiments, the acoustic wave filter is configured as a ladder filter.

In some embodiments, the acoustic wave filter is configured as a hybrid dual mode surface acoustic wave resonator/ladder filter.

In some embodiments, the acoustic wave filter is configured as one of a receive filter or a transmit filter of a duplexer.

In some embodiments, the acoustic wave filter is included in a diversity receive module.

In some embodiments, the plurality of acoustic wave resonators are surface acoustic wave resonators.

In some embodiments, the plurality of acoustic wave resonators are bulk acoustic wave resonators.

In some embodiments, the plurality of acoustic wave resonators include at least one surface acoustic wave resonator and at least one bulk acoustic wave resonator.

In some embodiments, the radio frequency filter is included in a radio frequency device module.

In some embodiments, the radio frequency device module is included in a radio frequency device.

In accordance with another aspect, there is provided an acoustic wave device configured as one of a duplexer or a diversity receive module and including at least one acoustic wave filter. The at least one acoustic wave filter comprises an input port, an output port, a plurality of acoustic wave resonators electrically connected between the input port and the output port, and an impedance matching acoustic wave resonator electrically connected on one side to a node between the plurality of acoustic wave resonators and one of the input port or the output port, and on a second side to one of ground or to the one of the input port or the output port, the impedance matching acoustic wave resonator having a resonance frequency below a low edge of a passband of the acoustic wave filter and an antiresonance frequency above a high edge of the passband of the acoustic wave filter, the impedance matching acoustic wave resonator being one of a surface acoustic wave resonator having a multilayer piezoelectric substrate or a bulk acoustic wave resonator.

In some embodiments, the impedance matching acoustic wave resonator is inductive at all frequencies within the passband of the acoustic wave filter.

In some embodiments, the plurality of acoustic wave resonators are surface acoustic wave resonators.

In some embodiments, the plurality of acoustic wave resonators are bulk acoustic wave resonators.

In some embodiments, the plurality of acoustic wave resonators include at least one surface acoustic wave resonator and at least one bulk acoustic wave resonator.

In some embodiments, the at least one acoustic wave filter is configured as a ladder filter.

In some embodiments, the at least one acoustic wave filter is configured as a hybrid dual mode surface acoustic wave resonator/ladder filter.

In some embodiments, the at least one acoustic wave filter is one of a receive filter or a transmit filter.

In some embodiments, the acoustic wave device is included in a radio frequency device.

### BRIEF DESCRIPTION OF THE DRAWINGS

FIG. 1A is a cross-sectional view of a portion of a surface acoustic wave (SAW) device having an interdigital transducer (IDT) structure arranged on a layer of piezoelectric material;

FIG. 1B is a cross-sectional view of a portion of a SAW device having an IDT structure arranged on a layer of piezoelectric material and a temperature compensation layer disposed on the IDT structure;

FIG. 1C is a top view on a SAW device having the IDT structure illustrated in FIG. 1A;

FIG. 2 is a cross-sectional view of an example of a bulk acoustic wave (BAW) device;

FIG. 3 illustrates an acoustic wave filter configured as a ladder filter;

FIG. 4 illustrates an acoustic wave filter configured as a dual mode SAW (DMS)/ladder hybrid filter;

FIG. 5 illustrates a duplexer including acoustic wave resonators;

FIG. 6 illustrates an example of a diversity receive module;

FIG. 7 illustrates the passband of an example of an acoustic wave filter as well as the admittance of an acoustic wave resonator that may be utilized as an inductive element in the filter;

FIG. 8 illustrates how quality factor and admittance of an example of an acoustic wave filter changes with frequency;

FIG. 9A illustrates a modification to the acoustic wave filter of FIG. 3;

FIG. 9B illustrates another modification to the acoustic wave filter of FIG. 3;

FIG. 10A illustrates a modification to the acoustic wave filter of FIG. 4;

FIG. 10B illustrates another modification to the acoustic wave filter of FIG. 4;

FIG. 11A illustrates a modification to the duplexer of FIG. 5;

FIG. 11B illustrates another modification to the duplexer of FIG. 5;

FIG. 12A illustrates a modification to the diversity receive module of FIG. 6;

FIG. 12B illustrates a modification to the diversity receive module of FIG. 6;

FIG. 13 is a block diagram of an example of a wireless device; and

FIG. 14 is a block diagram of an example of a wireless device including diversity receive functionality.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

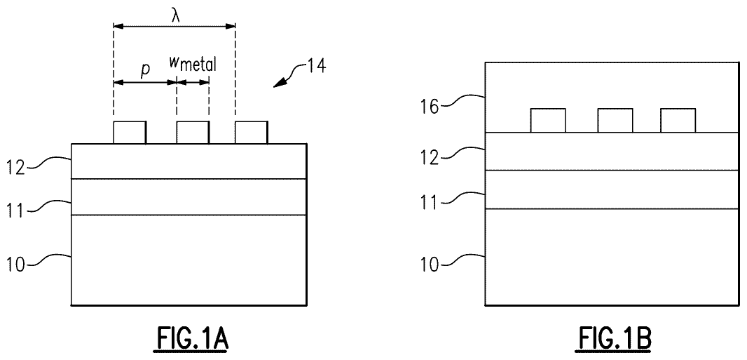

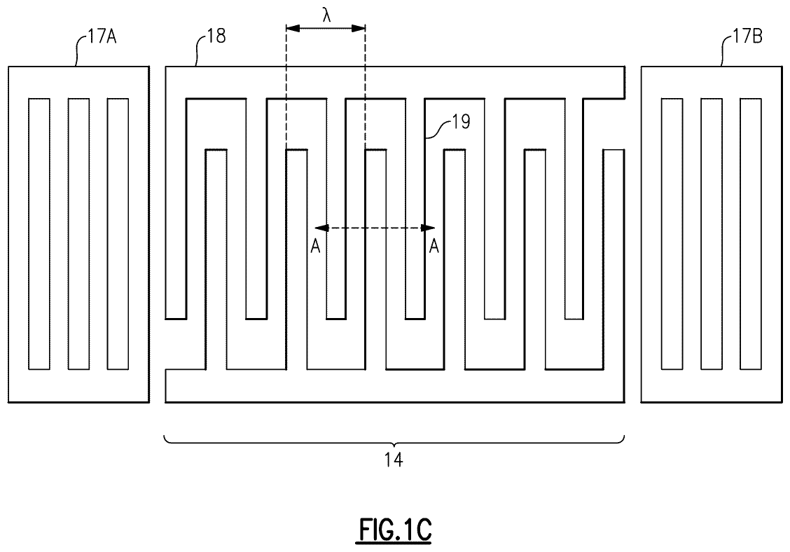

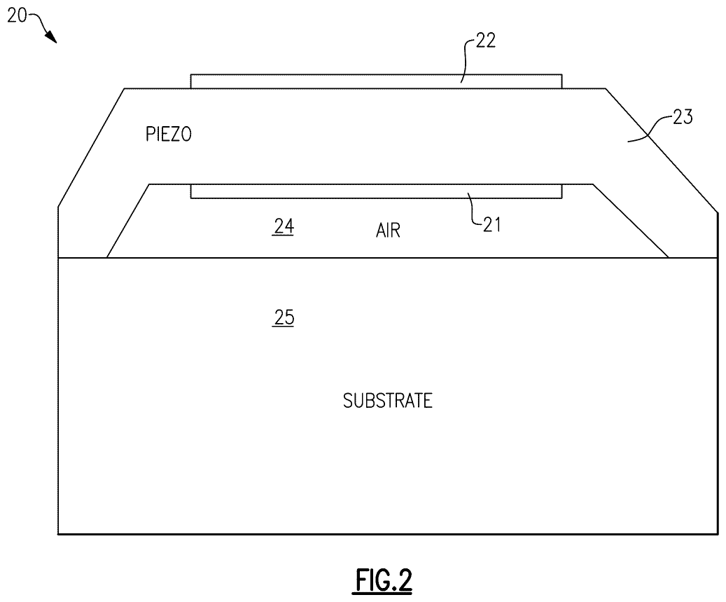

As noted above, a radio frequency acoustic wave filter, for example, a bandpass filter can be formed from a plurality of acoustic wave resonators. One form of acoustic wave resonator that may be utilized in a radio frequency acoustic wave filter is a surface acoustic wave (SAW) resonator. The structure of one example of a SAW resonator is illustrated in highly schematic form in FIGS. 1A-1C.

FIG. 1A is a cross-sectional view of an interdigital transducer (IDT) structure of a section of a SAW resonator having an IDT structure arranged on a piezoelectric material layer 12. The SAW resonator can be a temperature compensated SAW (TCSAW) resonator. The SAW resonator may include a multilayer piezoelectric (MPS) substrate. As illustrated, the SAW resonator includes a layer of piezoelectric material 12 formed over a functional layer 11, which can be made of silicon dioxide (SiO₂), for example, and IDT electrodes 14. The SiO₂ layer may be formed on a support substrate 10. The support substrate 10 may be formed of, for example, silicon, aluminum nitride, sapphire, silicon carbide, spinel, or another suitable material. The TCSAW device may comprise a temperature compensation layer 16 formed of, for example, SiO₂ over the IDT electrodes 14 as shown in FIG. 1B.

The piezoelectric material layer 12 can be a lithium-based piezoelectric material layer. For example, the piezoelectric material layer 12 can be a lithium niobate (LN) layer. As another example, the piezoelectric material layer 12 can be a lithium tantalate (LT) layer. The LT in the piezoelectric material layer 12 may be 42YX LT ((0°, −48°, 0°) in Euler angle notation) or may have a lower cut angle, for example, 20˜42 YX-LT ((0°, −70°˜−48°, 0°) in Euler angle notation).

In the TCSAW device, the IDT electrodes 14 are formed (for example, by sputtering) on the piezoelectric material layer 12. As illustrated, the IDT electrodes 14 have a first side in physical contact with the piezoelectric material layer 12 and a second side which may be in physical contact with the temperature compensation layer 16. The IDT electrodes 14 can include aluminum (Al), molybdenum (Mo), tungsten (W), gold (Au), silver (Ag), copper (Cu), platinum (Pt), ruthenium (Ru), titanium (Ti), the like, or any suitable combination or alloy thereof. The IDT electrodes 14 can be multi-layer IDT electrodes in some embodiments. A ratio of the IDT width (wₘₑₜₐₗ) to the pitch (p) is usually defined as duty factor (DF) or metallization ratio (wₘₑₜₐₗ/p).

In the TCSAW device, the temperature compensation layer 16 and/or the functional layer 11 can have a positive temperature coefficient of frequency (TCF). This can at least partially compensate for a negative TCF of the piezoelectric material layer 12. The piezoelectric material layer 12 can be lithium niobate or lithium tantalate, which both have a negative TCF. The temperature compensation layer 16 and/or the functional layer 11 can be a dielectric film. The temperature compensation layer 16 and/or the functional layer 11 can be a silicon dioxide (SiO₂) layer. In some other embodiments, a different temperature compensation layer can be implemented. Some examples of other temperature compensation layers include a tellurium dioxide (TeO₂) layer or a silicon oxyfluoride (SiOF) layer.

FIG. 1C is a top view of a SAW device having an IDT structure as illustrated in FIG. 1A. In FIG. 1C, the view of the SAW devices shown in FIG. 1A or FIG. 1B is along the dashed line from A to A. The temperature compensation layer is not shown in FIG. 1C. The IDT electrodes 14 are positioned between a first acoustic reflector 17A and a second acoustic reflector 17B. The acoustic reflectors 17A and 17B are separated from the IDT electrodes 14 by respective gaps. The IDT electrodes 14 includes bus bars 18 and IDT fingers 19 extending from the bus bars 18. The IDT fingers 19 have a pitch of p=λ/2, where λ denotes the wavelength of the main acoustic wave generated at the resonant frequency Fs of the SAW device. The SAW device can include any suitable number of IDT fingers 19.

Another form of acoustic wave resonator that may be used in an acoustic wave filter is a bulk acoustic wave (BAW) resonator. An example of a BAW resonator is illustrated in cross-section in a highly schematic form in FIG. 2. The illustrated BAW resonator 20 is a film bulk acoustic wave resonator. The BAW resonator 20 includes a first electrode 21, a second electrode 22, a piezoelectric material layer 23, an air cavity 24, and a substrate 25. The electrodes 21 and 22 are on opposing sides of the piezoelectric material layer 23. The piezoelectric material layer 23 can be a thin film. The piezoelectric material layer 23 can be an aluminum nitride layer, for example. The piezoelectric material layer 23 may be an aluminum nitride layer doped with an impurity such as scandium. In other instances, the piezoelectric material layer 23 can be any other suitable piezoelectric material layer. The air cavity 24 is disposed between the electrode 21 and the substrate 25. The substrate 25 can be a semiconductor substrate. For example, the substrate 25 can be a silicon substrate. The substrate 25 can be any other suitable substrate, such as a quartz substrate, a sapphire substrate, a spinel substrate, a ceramic substrate, a glass substrate, or the like. Although not shown in FIG. 2, the BAW resonator 20 can include a raised frame structure and/or a recessed frame structure.

Other forms of BAW resonators that may be utilized in acoustic wave filters, circuits, and devices as disclosed herein include solidly mounted resonators and Lamb wave resonators.

Parameters of acoustic wave filters desired by users include small size, low change in performance, for example, passband frequency, with changes in temperature, often referred to as low temperature coefficient of frequency (TCF), high quality factor (Q), low insertion loss, and large bandwidth with steep passband edges to accommodate newer high bandwidth radio frequency communication bands.

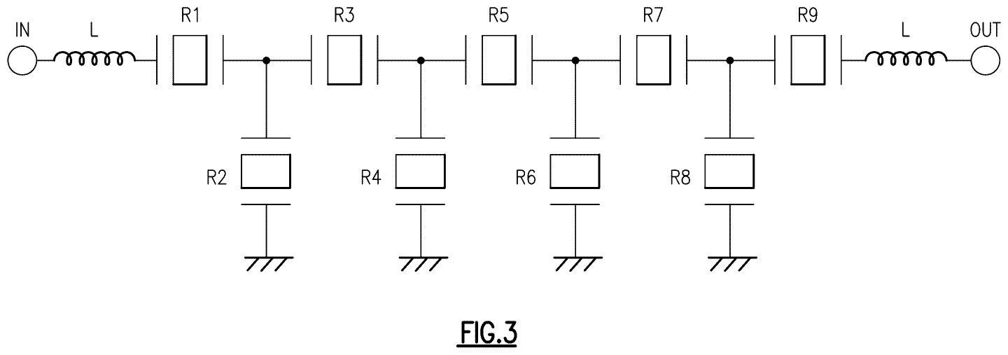

One simplified example of an acoustic wave filter having a ladder filter configuration is illustrated in FIG. 3. The acoustic wave filter includes series resonators R1, R3, R5, R7, and R9 electrically connected in series between an input port and an output port. Shunt resonators R2, R4, R6, and R8 are electrically connected between nodes between adjacent series resonators and ground. The resonators R1-R9 may be SAW resonators or BAW resonators. The acoustic wave filter may further include inductors L between resonator R1 and the input port and/or between resonator R9 and the output port. The inductor(s) L are used to match the input or output impedance of the acoustic wave filter to the impedance of other circuitry that may be coupled to the input or output ports to minimize the reflection of signals to or from the other circuitry. The inductor(s) L may be surface mount devices that are mounted to a packaging substrate along with a die including the resonators of the filter or may be formed as a spiral shaped metal trace formed on the same die as the resonators or on a different die. In either form, the inductor(s) take up valuable space on the packaging substrate for the filter or on the resonator die and will typically have a low quality factor that may negatively impact the insertion loss of the filter. The inductor(s) L may also increase the cost of the acoustic wave filter due to the increased form factor, cost of the inductor(s) in surface mount device configurations, or due to extra fabrication steps to form the inductor(s) as spiral wound metal trace(s).

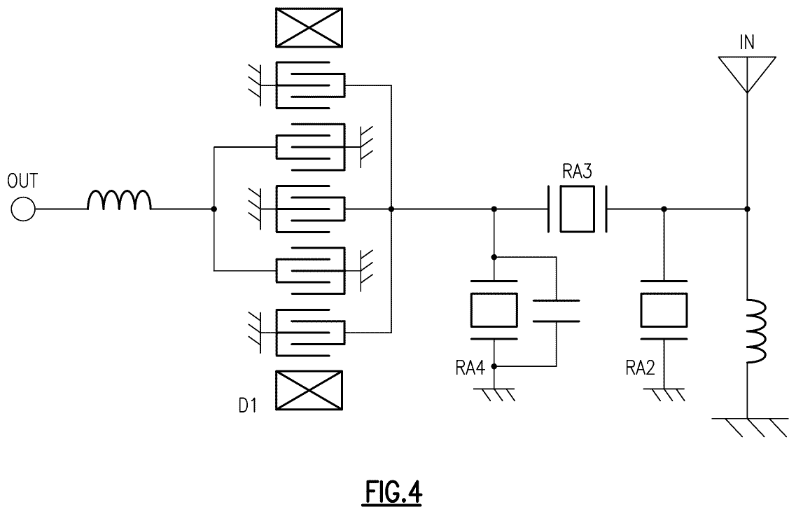

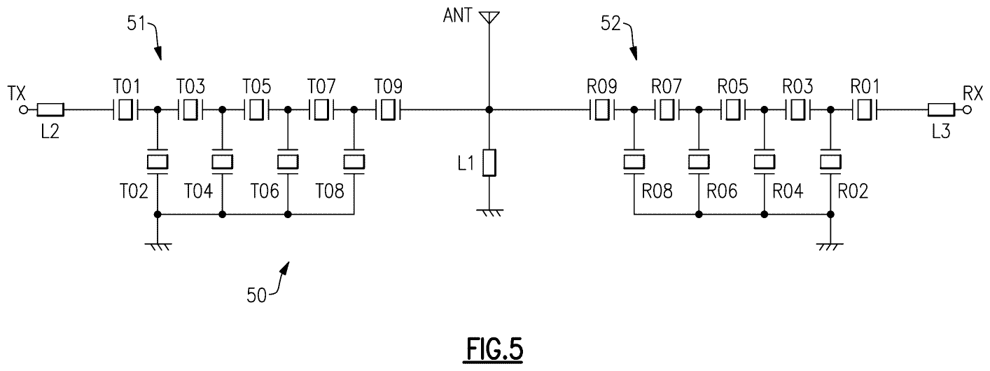

FIG. 4 illustrates another example of an acoustic wave filter utilized as a receive filter for an electronic device. The acoustic wave filter of FIG. 4 is a hybrid dual mode SAW (DMS) and ladder filter. The ladder portion includes series resonator RA3 and shunt resonators RA2 and RA4. The ladder portion of the acoustic wave filter is electrically connected between an antenna and a DMS portion D1. An inductor is provided between the DMS portion D1 and the output port of the filter for impedance matching. The inductor of the acoustic wave filter of FIG. 4 may be a surface mount device or a spiral metal trace like the inductor(s) of the ladder filter of FIG. 3 and may lead to similar disadvantages with respect to increasing the footprint, insertion loss, and cost of the filter.

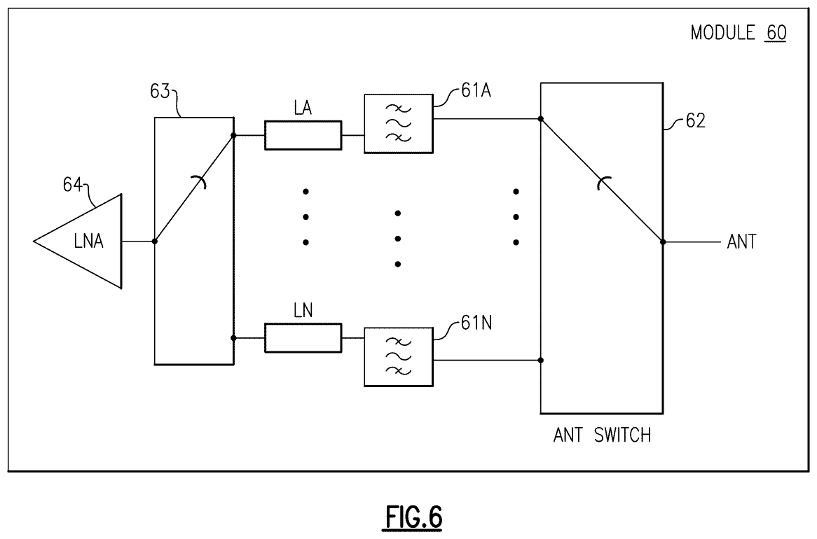

In another example, a receive side acoustic wave filter and a transmit side acoustic wave filter may be used together to form a duplexer, for example, as illustrated in FIG. 5, indicated generally at 50. The duplexer 50 can include a transmit filter 51 and a receive filter 52 coupled to each other at an antenna node ANT. A shunt inductor L1 can be connected to the antenna node ANT. The transmit filter 51 and the receive filter 52 can both be acoustic wave ladder filters.

The transmit filter 51 can filter a radio frequency signal and provide a filtered radio frequency signal to the antenna node ANT. A series inductor L2 can be coupled between a transmit input node TX and the acoustic wave resonators of the transmit filter 51. The illustrated transmit filter 51 can include acoustic wave resonators T01 to T09. One or more of these resonators can be BAW resonators or SAW resonators. The illustrated receive filter 52 can include acoustic wave resonators R01 to R09. One or more of these resonators can be a BAW resonators or SAW resonators. The receive filter 52 can filter a radio frequency signal received at the antenna node ANT. A series inductor L3 can be coupled between the resonators and a receive output node RX. The receive output node RX of the receive filter 52 provides a radio frequency receive signal.

The inductors L2 and L3 of the duplexer of FIG. 5 may be surface mount devices or spiral metal traces like the inductor(s) of the ladder filter of FIG. 3 and may lead to similar disadvantages with respect to increasing the footprint and the insertion loss of the transmit and receive filters as well as the overall cost of the duplexer.

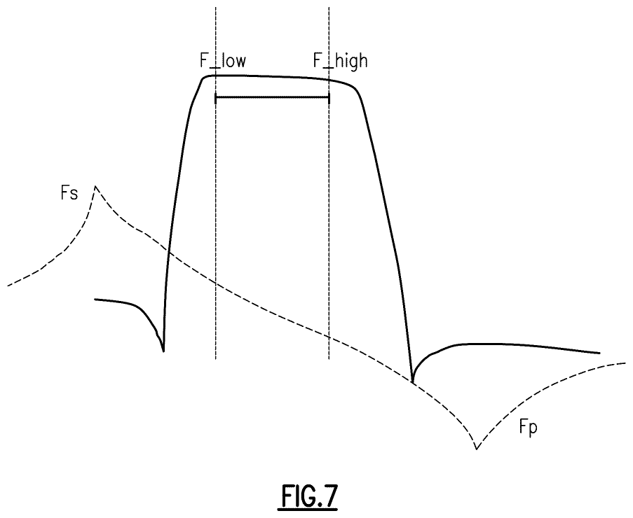

Another example of a module utilizing acoustic wave filters is a diversity receive module such as that illustrated schematically at 60 in FIG. 6. The diversity receive module 60 includes a plurality of filters 61A-61N that may operate in different frequency bands and that may be selectively electrically connected to an antenna by an antenna switch 62. Received signals from a selected filter pass through a radio frequency switch 63 to a low noise amplifier (LNA) 64. Inductors LA-LN may be provided in the receive signal path of each respective one of the plurality of filters to move the contour to achieve a desired gain and impedance and a low noise figure. The inductors LA-LN are typically surface mount devices.

Applicants have discovered that conventional inductors used in acoustic wave filter devices such as those described above as well as, for example, multiplexers or other forms of acoustic wave filter devices may be replaced with single port acoustic wave resonators, either SAW or BAW, disposed in shunt or series configuration at the location(s) in the filter circuits where the inductor(s) would typically be disposed.

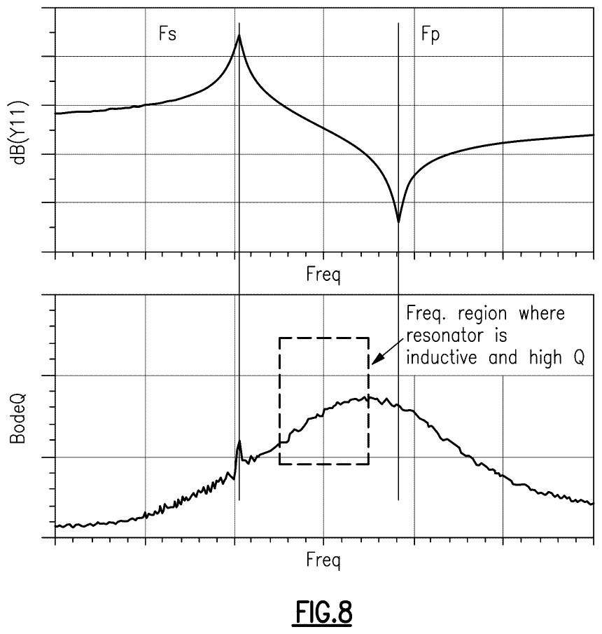

A single port acoustic wave resonator exhibits a resonance frequency Fs and an antiresonance frequency Fp with Fp being at a higher frequency than Fs. The single port acoustic wave resonator is capacitive at frequencies below Fs and above Fp, but inductive in the frequency range between Fs and Fp. If one were to design a single port acoustic wave resonator with a sufficiently high electromechanical coupling coefficient kt2 such that the difference in frequency between its Fs and Fp frequencies was greater than the passband of an acoustic wave filter of interest and such that Fs of the resonator was below the low edge F_low of the filter passband and Fp of the resonator was above the high edge F_high of the filter passband, for example, as illustrated in FIG. 7, the single port acoustic wave resonator could then be used in place of the inductor(s) of the filter circuit. With Fs of the resonator being below the low edge F_low of the filter passband and Fp of the resonator being above the high edge F_high of the filter passband the frequency range in which the resonator is inductive covers the whole of the filter passband. This would provide advantages with respect to reducing the size of the filter die or package because acoustic wave resonators may be formed significantly smaller than inductors. Further, an acoustic wave resonator may exhibit a quality factor significantly higher than an inductor, for example, a quality factor in the hundreds for an acoustic wave resonator as opposed to a quality factor in the tens for an inductor, with the highest quality factor being exhibited between the Fs and Fp frequencies of the resonator as illustrated in FIG. 8.

There are multiple ways known in the art to change the electromechanical coupling factor kt2 of an acoustic wave resonator, and hence the difference between its Fs and Fp frequencies. For example, for SAW resonators kt2 generally increases as the thickness of the piezoelectric material layer of the SAW resonator is increased or as the crystallographic cut angle of the piezoelectric material layer is decreased. For BAW resonators, kt2 generally increases with increased doping of the piezoelectric material layer with, for example, Sc. The frequencies at which Fs and Fp of a SAW resonator occur may be adjusted by changing the pitch or thickness of the IDT electrodes of the resonator. The frequencies at which Fs and Fp of a BAW resonator occur may be adjusted by changing the thickness of the piezoelectric material layer. Aspects and embodiments disclosed herein are not limited to any particular method of adjusting kt2, Fs, or Fp of an acoustic wave resonator utilized as an inductive element in an acoustic wave filter.

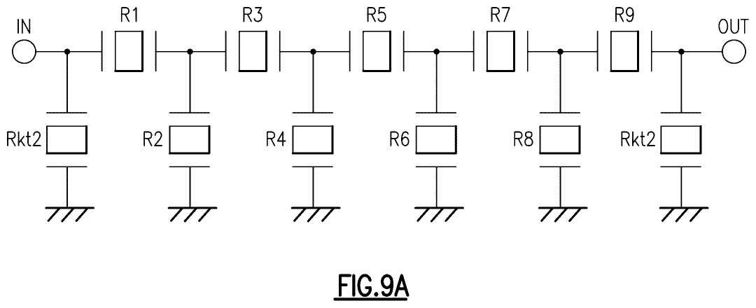

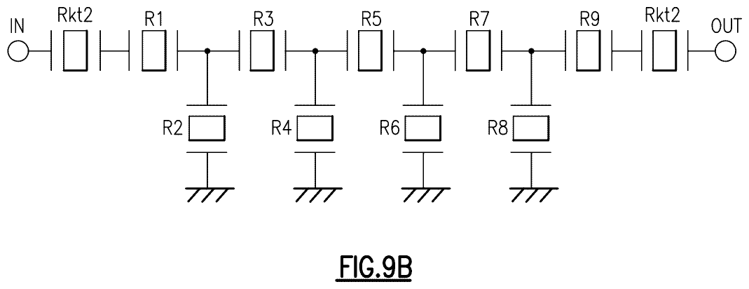

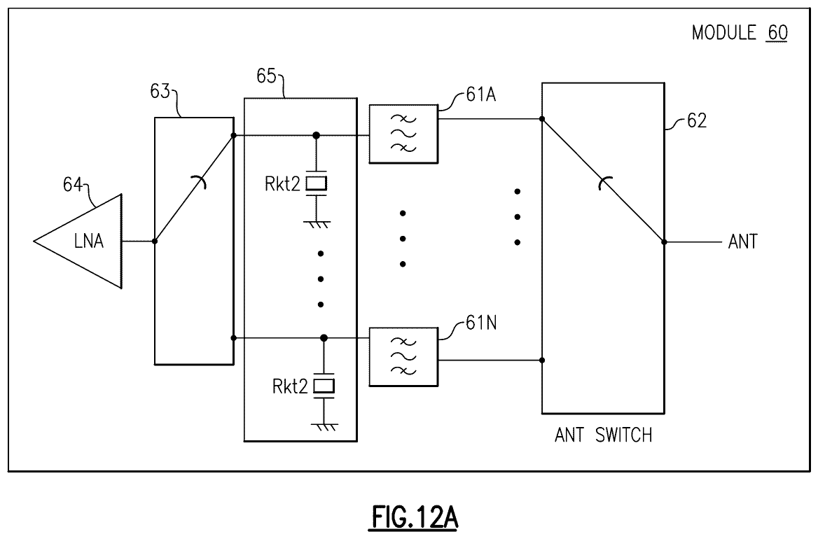

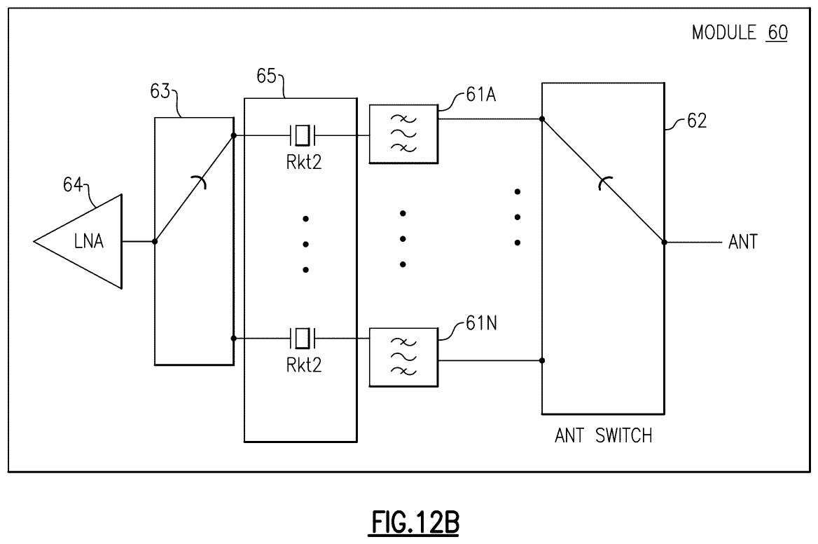

In accordance with embodiments of the present disclosure, inductors in acoustic wave filter circuits such as described with reference to FIGS. 3-6 above may be replaced with high kt2 acoustic wave resonators Rkt2 in a shunt and/or series configuration. These high kt2 acoustic wave resonators Rkt2 may be referred to herein as impedance matching acoustic wave resonators. Fs of the high kt2 acoustic wave resonators should be below the respective filter passband low edge and Fp of the high kt2 acoustic wave resonators should be above the respective filter passband high edge as discussed above. For example, the circuits illustrated in FIGS. 3-6 above may be modified as illustrated in FIGS. 9A-12B, respectively. The high kt2 acoustic wave resonators Rkt2 may be formed on the same die as other resonators in the filter circuits or on a separate die with multiple of the high kt2 acoustic wave resonators Rkt2 forming filter bank, for example, as illustrated at 65 in FIG. 12.

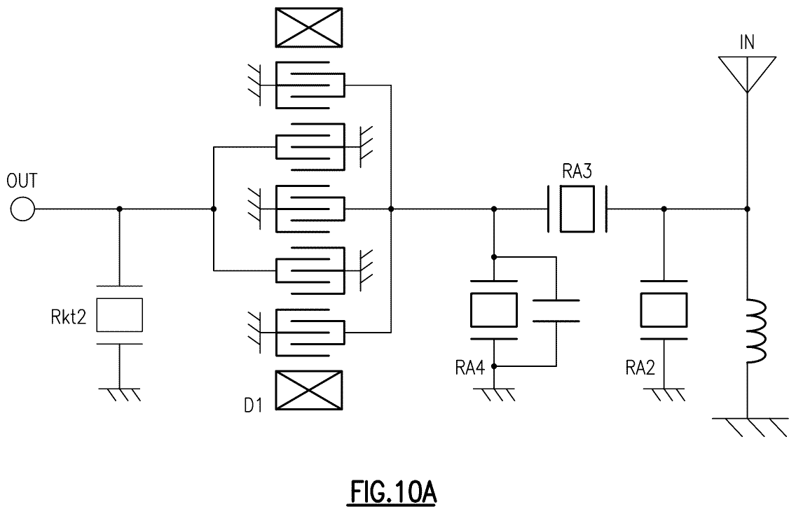

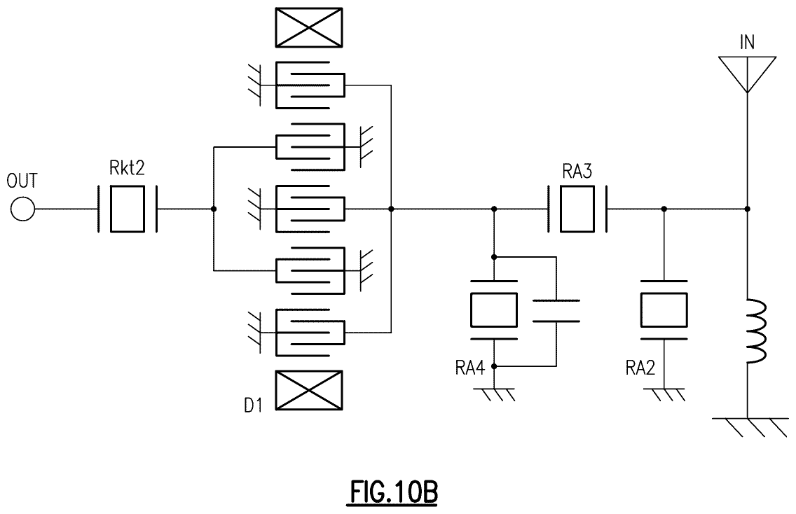

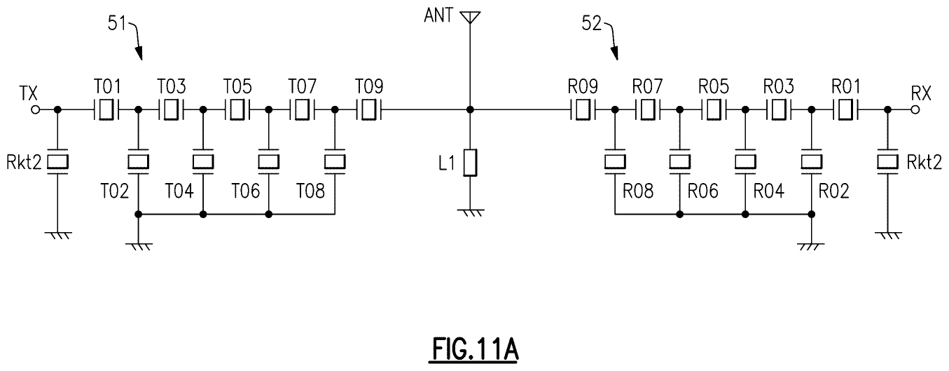

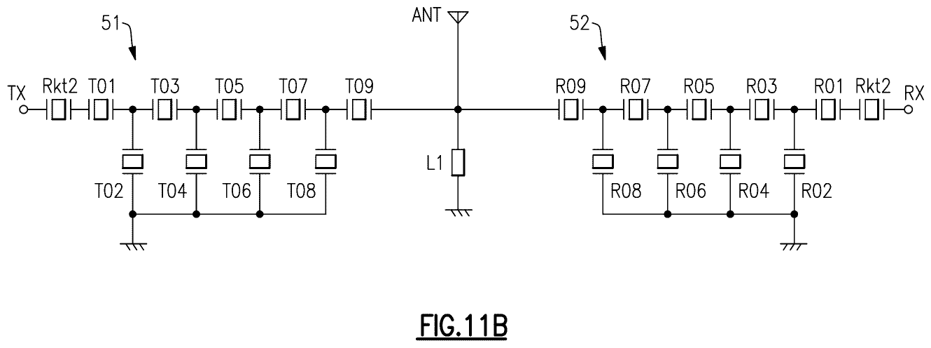

In FIGS. 9A, 10A, 11A, and 12A, inductors in the acoustic wave filter circuits such as described with reference to FIGS. 3-6 above, respectively, are replaced by high kt2 acoustic wave resonators in shunt configurations. In FIGS. 9B, 10B, 11B, and 12B, inductors in the acoustic wave filter circuits such as described with reference to FIGS. 3-6 above, respectively, are replaced by high kt2 acoustic wave resonators in series configurations. It is to be appreciated that the embodiments of FIGS. 9A and 9B, of FIGS. 10A and 10B, of FIGS. 11A and 11B, and of FIGS. 12A and 12B may be combined or modified in view of one another such that the acoustic wave filter circuits included high kt2 acoustic wave resonators in both series and shunt configurations or with one or more high kt2 acoustic wave resonators in series configuration and one or more other high kt2 acoustic wave resonators in shunt configuration.

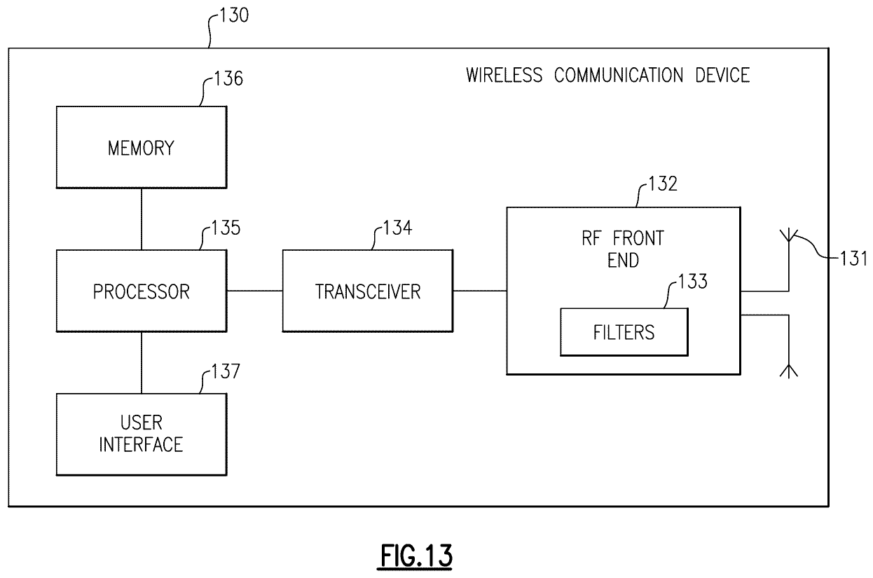

One or more filters with any suitable number of acoustic wave resonators can be implemented in a variety of wireless communication devices. FIG. 13 is a schematic block diagram of an example wireless communication device 130 that includes a filter 133 with one or more acoustic wave resonators in accordance with any suitable principles and advantages disclosed herein. The wireless communication device 130 can be any suitable wireless communication device. For instance, a wireless communication device 130 can be a mobile phone, such as a smartphone. As illustrated, the wireless communication device 130 includes one or more antennas 131, a radio frequency (RF) front end 132 that includes filter 133, an RF transceiver 134, a processor 135, a memory 136, and a user interface 137. The one or more antennas 131 can transmit RF signals provided by the RF front end 132. The one or more antennas 131 can provide received RF signals to the RF front end 132 for processing.

The RF front end 132 can include one or more power amplifiers, one or more low noise amplifiers, RF switches, receive filters, transmit filters, duplex filters, filters of a multiplexer, filters of a diplexer or other frequency multiplexing circuit, or any suitable combination thereof. The RF front end 132 can transmit and receive RF signals associated with any suitable communication standards. Any of the acoustic wave filters disclosed herein, or portions thereof, can be implemented in filters 133 of the RF front end 132.

The RF transceiver 134 can provide RF signals to the RF front end 132 for amplification and/or other processing. The RF transceiver 134 can also process an RF signal provided by a low noise amplifier of the RF front end 132. The RF transceiver 134 is in communication with the processor 135. The processor 135 can be a baseband processor. The processor 135 can provide any suitable base band processing functions for the wireless communication device 130. The memory 136 can be accessed by the processor 135. The memory 136 can store any suitable data for the wireless communication device 130. The processor 135 is also in communication with the user interface 137. The user interface 137 can be any suitable user interface, such as a display.

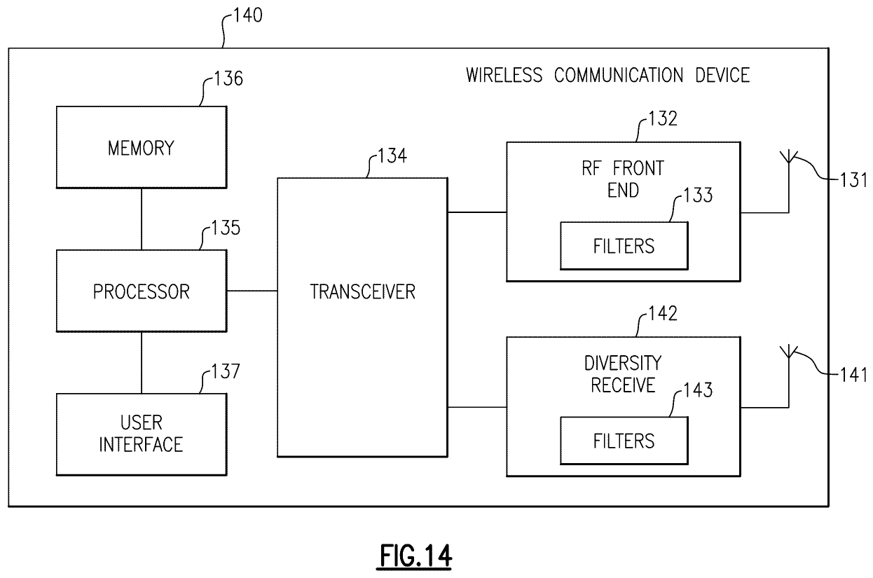

FIG. 14 is a schematic diagram of a wireless communication device 140 that includes filters 133 in a radio frequency front end 132 and second filters 143 in a diversity receive module 142. The wireless communication device 140 is like the wireless communication device 130 of FIG. 13, except that the wireless communication device 140 also includes diversity receive features. As illustrated in FIG. 14, the wireless communication device 140 can include a diversity antenna 141, a diversity module 142 configured to process signals received by the diversity antenna 141 and including filters 143, and a transceiver 134 in communication with both the radio frequency front end 132 and the diversity receive module 142. One or more of the second filters 143 can include acoustic wave resonators in accordance with any suitable principles and advantages disclosed herein.

Acoustic wave filters as disclosed herein may be arranged to filter a radio frequency signal in a fifth generation (5G) New Radio (NR) operating band within Frequency Range 1 (FR1). FR1 can span frequencies from 410 megahertz (MHz) to 7.125 gigahertz (GHz), for example, as specified in a current 5G NR specification. A filter arranged to filter a radio frequency signal in a 5G NR FR1 operating band can include one or more acoustic wave resonators and may be implemented in accordance with any suitable principles and advantages disclosed herein.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An acoustic wave filter comprising:
an input port;
an output port;
a plurality of acoustic wave resonators electrically connected between the input port and the output port; and
an impedance matching acoustic wave resonator electrically connected on one side to a node between the plurality of acoustic wave resonators and one of the input port or the output port, and on a second side to one of ground or to the one of the input port or the output port, the impedance matching acoustic wave resonator having a resonance frequency below a low edge of a passband of the acoustic wave filter and an antiresonance frequency above a high edge of the passband of the acoustic wave filter, the impedance matching acoustic wave resonator being one of a surface acoustic wave resonator having a multilayer piezoelectric substrate or a bulk acoustic wave resonator.

2. The acoustic wave filter of claim 1 wherein the impedance matching acoustic wave resonator is inductive at all frequencies within the passband of the acoustic wave filter.

3. The acoustic wave filter of claim 1 configured as a ladder filter.

4. The acoustic wave filter of claim 1 configured as a hybrid dual mode surface acoustic wave resonator/ladder filter.

5. The acoustic wave filter of claim 1 configured as one of a receive filter or a transmit filter of a duplexer.

6. The acoustic wave filter of claim 1 included in a diversity receive module.

7. The acoustic wave filter of claim 1 wherein the plurality of acoustic wave resonators are surface acoustic wave resonators.

8. The acoustic wave filter of claim 1 wherein the plurality of acoustic wave resonators are bulk acoustic wave resonators.

9. The acoustic wave filter of claim 1 wherein the plurality of acoustic wave resonators include at least one surface acoustic wave resonator and at least one bulk acoustic wave resonator.

10. A radio frequency device module including the radio frequency filter of claim 1.

11. A radio frequency device including the radio frequency device module of claim 10.

12. An acoustic wave device configured as one of a duplexer or a diversity receive module and including at least one acoustic wave filter comprising:
an input port;
an output port;
a plurality of acoustic wave resonators electrically connected between the input port and the output port; and
an impedance matching acoustic wave resonator electrically connected on one side to a node between the plurality of acoustic wave resonators and one of the input port or the output port, and on a second side to one of ground or to the one of the input port or the output port, the impedance matching acoustic wave resonator having a resonance frequency below a low edge of a passband of the acoustic wave filter and an antiresonance frequency above a high edge of the passband of the acoustic wave filter, the impedance matching acoustic wave resonator being one of a surface acoustic wave resonator having a multilayer piezoelectric substrate or a bulk acoustic wave resonator.

13. The acoustic wave device of claim 12 wherein the impedance matching acoustic wave resonator is inductive at all frequencies within the passband of the acoustic wave filter.

14. The acoustic wave device of claim 12 wherein the plurality of acoustic wave resonators are surface acoustic wave resonators.

15. The acoustic wave device of claim 12 wherein the plurality of acoustic wave resonators are bulk acoustic wave resonators.

16. The acoustic wave device of claim 12 wherein the plurality of acoustic wave resonators include at least one surface acoustic wave resonator and at least one bulk acoustic wave resonator.

17. The acoustic wave device of claim 12 wherein the at least one acoustic wave filter is configured as a ladder filter.

18. The acoustic wave device of claim 12 wherein the at least one acoustic wave filter is configured as a hybrid dual mode surface acoustic wave resonator/ladder filter.

19. The acoustic wave device of claim 12 wherein the at least one acoustic wave filter is one of a receive filter or a transmit filter.

20. A radio frequency device including the acoustic wave device of claim 12.
